(19) United States
(12) Patent Application Publication
(10) Pub. No.: US 2014/0186983 A1
(43) Pub. Date: Jul. 3, 2014

(54) MASK, METHOD OF CLEANING THE MASK, AND METHOD OF MANUFACTURING A PLURALITY OF ORGANIC ELECTROLUMINESCENT ELEMENTS USING THE MASK

(71) Applicants: Eung Do KIM, Yongin-City (KR); Won Jong KIM, Yongin-City (KR); Kyu Hwan HWANG, Yongin-City (KR); Seok Gyu YOON, Yongin-City (KR); Dong Chan KIM, Yongin-City (KR); Bo Ra JUNG, Yongin-City (KR); Dong Kyu SEO, Yongin-City (KR); Young Woo SONG, Yongin-City (KR); Jong Hyuk LEE, Yongin-City (KR)

(72) Inventors: Eung Do KIM, Yongin-City (KR); Won Jong KIM, Yongin-City (KR); Kyu Hwan HWANG, Yongin-City (KR); Seok Gyu YOON, Yongin-City (KR); Dong Chan KIM, Yongin-City (KR); Bo Ra JUNG, Yongin-City (KR); Dong Kyu SEO, Yongin-City (KR); Young Woo SONG, Yongin-City (KR); Jong Hyuk LEE, Yongin-City (KR)

(21) Appl. No.: 13/944,007

(22) Filed: Jul. 17, 2013

(30) Foreign Application Priority Data
Jan. 3, 2013 (KR) 10-2013-0000629

(51) Int. Cl. H01L 51/00

(52) U.S. Cl. CPC H01L 51/0023
USPC 438/46; 438/654; 428/457

(57) ABSTRACT

A method of cleaning a mask includes preparing a mask on which a first metal layer and a second metal layer are stacked sequentially, and lifting off the second metal layer by removing the first metal layer.

This application claims priority to Korean Patent Application No. 10-2013-0000629, filed on Jan. 3, 2013, in the Korean Intellectual Property Office, the disclosure of which is incorporated herein by reference in its entirety.

### BACKGROUND

1. Field

Embodiments relate to a mask, a method of cleaning the mask, and a method of manufacturing a plurality of organic electroluminescent elements using the mask.

2. Description of the Related Art

Of display devices which display images, organic electroluminescent display devices are drawing attention as next-generation display devices due to their wide viewing angle, high contrast, and fast response time.

An organic electroluminescent display device includes organic electroluminescent elements. Generally, an organic electroluminescent element has a stacked structure including an anode, a cathode, and an emission layer inserted between the anode and the cathode. The organic electroluminescent element displays a color when holes and electrons, injected respectively from the anode and the cathode, recombine in the emission layer to emit light. Additionally, intermediate layers including a hole injection layer, a hole transfer layer, an electron transfer layer and an electron injection layer are selectively inserted between the emission layer and each of the electrodes.

### SUMMARY

Embodiments are directed to a method of cleaning a mask, the method including preparing a mask on which a first metal layer and a second metal layer are stacked sequentially, and lifting off the second metal layer by removing the first metal layer.

The first metal layer may include one or more of an alkali metal or an alkali earth metal.

The first metal layer may include the alkali earth metal, the alkali earth metal being magnesium.

The first metal layer may further include silver, and a ratio of the number of magnesium atoms to the number of silver atoms may be from 1:1 to about 10:1.

The second metal layer may be more adhesive, relative to the mask, than the first metal layer.

The second metal layer may include ytterbium and an alloy, the alloy being an alloy of silver and magnesium in which silver is dominant, the second metal layer being formed in connection with forming a cathode layer.

The second metal layer may be formed by alternately depositing the ytterbium and the alloy.

At least a portion of the first metal layer may be overlapped by the second metal layer.

The lifting off of the second metal layer by removing the first metal layer may include removing the first metal layer using an aqueous alkali solution.

The aqueous alkali solution may include one or more of sodium hydroxide or potassium hydroxide.

Embodiments are also directed to a method of manufacturing a plurality of organic electroluminescent elements, the method including depositing a second metal layer, the second metal layer being deposited on a first substrate and on a mask coated with a first metal layer, lifting off the second metal layer by removing the first metal layer from the mask, coating the mask with a third metal layer, and depositing a fourth metal layer on a second substrate and on the mask coated with the third metal layer.

The first metal layer may include one or more of an alkali metal or an alkali earth metal.

The first metal layer and the third metal layer may be made of a same material.

The second metal layer may be more adhesive, relative to the mask, than the first metal layer.

The second metal layer and the fourth metal layer may be made of a same material.

The lifting off of the second metal layer by removing the first metal layer may include removing the first metal layer using an aqueous alkali solution.

Embodiments are also directed to a method of manufacturing a plurality of organic electroluminescent elements, the method including depositing a first metal layer on a first substrate and on a mask, depositing a second metal layer on a second substrate and on the mask having the first metal layer deposited thereon, and lifting off the second metal layer by removing the first metal layer from the mask.

The first metal layer may include one or more of an alkali metal or an alkali earth metal.

The second metal layer may be more adhesive, relative to the mask, than the first metal layer.

The lifting off of the second metal layer by removing the first metal layer may include removing the first metal layer using an aqueous alkali solution.

Embodiments are also directed to a mask coated with a metal layer, the metal layer including one or more of an alkali metal or an alkali earth metal.

The metal layer may include the alkali earth metal, the alkali earth metal being magnesium.

The metal layer may further include silver, and a ratio of the number of magnesium atoms to the number of silver atoms may be from 1:1 to about 10:1.

### BRIEF DESCRIPTION OF THE DRAWINGS

Features will become apparent to those of skill in the art by describing in detail example embodiments with reference to the attached drawings in which:

FIG. 1 is a cross-sectional view showing the basic structure of an organic electroluminescent element;

FIG. 2 is a cross-sectional view of a mask according to an embodiment;

FIGS. 3 and 4 are cross-sectional views illustrating a method of cleaning a mask according to an embodiment;

FIGS. 5 through 8 are cross-sectional views illustrating a method of manufacturing a plurality of organic electroluminescent elements according to an embodiment; and

FIGS. 9 through 11 are cross-sectional views illustrating a method of manufacturing a plurality of organic electroluminescent elements according to another embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “on” another element, it may be directly on the other element, or one or more intervening elements may also be present. It will also be understood that when an element is referred to as being “under” another element, it may be directly under, or one or more intervening elements may also be present. It will also be understood that when an element is referred to as being “between” two elements, it may be the only element between the two elements, or one or more intervening elements may also be present. Like reference numerals refer to like elements throughout.

Although the terms “first,” “second,” and so forth are used to describe diverse constituent elements, such constituent elements are not limited by the terms. The terms are used only to discriminate a constituent element from other constituent elements. Accordingly, in the following description, a first constituent element may be a second constituent element.

FIG. 1 is a cross-sectional view showing the basic structure of an organic electroluminescent element. Referring to FIG. 1, the organic electroluminescent element may include metal layers made of metals and organic layers made of organic materials. The metal layers may include an anode layer 11 and a cathode layer 15, and the organic layers may include a hole transfer layer (HTL) 12, an emission layer (EML) 13, and an electron transfer layer (ETL) 14. In addition, the organic layers may further include an oxide semiconductor layer, a hole injection layer (HIL), or an electron injection layer (EIL).

In the organic electroluminescent element, the organic layers are typically interposed between the metal layers. In the present example, the HTL 12, the EML 13, the ETL 14, and the cathode layer 15 are stacked sequentially on the anode layer 11.

The anode layer 11 may provide holes to the EML 13. The anode layer 11 may be made of a metal such as indium oxide (InO), zinc oxide (ZnO), tin oxide (SnO), indium tin oxide (ITO) which is a complex thereof, indium zinc oxide (IZO), gold (Au), platinum (Pt), silver (Ag), copper (Cu), etc.

The HTL 12 may transfer holes received from the anode layer 11 to the EML 13. The HTL 12 may be made of TPD (N,N′-bis(3-methylphenyl)-N,N-diphenyl-[1,1-biphenyl]-4,4′-diamine, NPD (N,N-di(naphthalene-1-yl)-N,N′-diphenyl benzidine, NPB (N,N′-diphenyl-N,N′-bis(1-naphthyl)-(1,1′-biphenyl-4,4′-diamine), etc.

The EML 13 may generate light by recombining holes received from the anode layer 11 and electrons received from the cathode layer 15. The EML 13 may include a light-emitting material or a combination of a host and a dopant. Examples of the host include, but are not limited to, Alq₃, CBP (4,4′-N,N′-dicarbazole-biphenyl), PVK (poly(n-vinylcarbazole), ADN (9,10-di(naphthalene-2-yl)anthracene), TCTA, TPBI ((1,3,5-tris(N-phenylbenzimidazole-2-yl)benzene), TBADN ((3-tert-butyl-9,10-di(naphth-2-yl)anthracene), E3, and DSA (distyrylarylene). Examples of a red dopant include, but are not limited to, PtOEP, Ir(piq)₃, and Btp₂Ir(acac). Examples of a green dopant include, but are not limited to, Ir(ppy)₃, Ir(ppy)₂(acac), and Ir(mpyp)₃. Examples of a blue dopant include, but are not limited to, F₂lrpic, (F₂ ppy)₂Ir(tmd), Ir(dfppz)₃, ter-fluorene, DPAVBi (4,4′-bis(4-diphenylaminostyryl)biphenyl), and TBPe (2,5,8,11-tetra-t-butylperylene).

The ETL 14 may transfer electrons received from the cathode layer 15 to the EML 13. The ETL 14 may be made of an electron transfer material. Examples of the electron transfer material include, but are not limited to, Bphen (4,7-diphenyl-1,10-phenanthroline), BAlq, Alq3 (tris(8-quinolate)aluminum), Bebq2 (beryllium bis(benzoquinolin-10-olate)), and TPBI.

The cathode layer 15 may provide electrons to the EML 13. The cathode layer 15 may be made of a metal identical to or different from the metal that forms the anode layer 11.

The HIL may be inserted between the anode layer 11 and the HTL 12 in order to improve a hole transfer function, and the EIL may be inserted between the cathode layer 15 and the ETL 14 to improve an electron transfer function. Additionally, an oxide semiconductor layer may be formed directly on the anode layer 11.

The stacked structure of the organic electroluminescent element described above may be obtained using a deposition method. Deposition is a technique of forming a layer on a surface of a substrate using vapor of a source. It is based on the principle that vapor, e.g., generated by heating a source in a container to a vaporization temperature, moves out of the container and then condenses on a substrate to be coated. Here, the source may be a material that forms a metal layer or an organic layer.

When a source is deposited on a substrate, a metal layer or an organic layer may be formed on the substrate. The metal or organic layer may adhere to another metal or organic layer already formed on the substrate. Here, “adhere” may denote “attach.” Thus, the metal or organic layer may be attached and fixed to the substrate or to another metal or organic layer already formed on the substrate.

A mask may be used to form a pattern on a substrate. Generally, a mask (e.g., a fine metal mask or an open mask) having a pattern may be inserted between a substrate and a deposition source which includes a source, and then a deposition process may be performed. If the deposition process is performed after the insertion of the mask, a metal layer or an organic layer may be deposited on both the substrate and the mask.

The mask on which the metal layer or the organic layer is deposited may be reused a predetermined number of times. However, it is desirable to clean the mask immediately in order to prevent contamination during a process or non-uniformity of a deposition pattern.

Generally, a metal layer is more adhesive, relative to the mask, than an organic layer. Therefore, after a metal layer is deposited using a mask, it may be difficult to completely remove the metal layer deposited on the mask. In addition, a metal layer having greater adhesion may be used as an electrode in order to improve characteristics of an organic electroluminescent element. However, it may be more difficult to clean a mask on which such a metal layer is deposited.

A mask that is used to deposit a metal layer of an organic electroluminescent element and which may be cleaned easily will now be described in detail with reference to FIG. 2. FIG. 2 is a cross-sectional view of a mask 200 according to an embodiment.

Referring to FIG. 2, a metal layer 300 that includes one or more of an alkali metal or an alkali earth metal is coated on the mask 200 according to the present example embodiment. Here, examples of the alkali metal include elements in group 1 of the periodic table, such as lithium (Li), sodium (Na), potassium (K), rubidium (Rb), cesium (Cs), and francium (Fr). Examples of the alkali earth metal may include elements in group 2 of the period table, such as calcium (Ca), strontium (Sr), barium (Ba), radium (Ra), beryllium (Be), and magnesium (Mg).

In an example embodiment, the metal layer 300 may include Mg only. In an example embodiment, the metal layer 300 may include an Mg—Ag alloy by adding Ag to Mg. In an example embodiment, a ratio of the number of Mg atoms to the number of Ag atoms in the Mg—Ag alloy may be from 1:1 to about 10:1. In an example embodiment, a ratio of the number of Mg atoms to the number of Ag atoms in the Mg—Ag alloy may be more than 1:1. In an example embodiment, a ratio of the number of Mg atoms to the number of Ag atoms in the Mg—Ag alloy may be more than 1:1 and less than 10:1. The Mg—Ag alloy may be an Mg-dominant alloy.

In an example embodiment, the metal layer 300 may further include Liq (8-quinolinolato lithium) in addition to the Mg—Ag alloy. The metal layer 300 may be a layer formed by repeatedly alternating a Liq layer and an Mg—Ag alloy layer.

The metal layer 300 that includes one or more of the alkali metal or the alkali earth metal may be less adhesive, relative to the mask 200, than another metal layer used in forming an organic electroluminescent element. Therefore, even if a process of depositing another metal layer of an organic electroluminescent element is performed using the mask 200 coated with the metal layer 300, that is, even if another metal layer is deposited on the mask 200, since the metal layer 300 which directly contacts the mask 200 has relatively weak adhesion to the mask, the deposited metal layer may be lifted off by removing the metal layer 300. Therefore, the mask 200 may be cleaned easily.

The metal layer 300 that includes one or more of the alkali metal or the alkali earth metal may be removed using an aqueous alkali solution. Thus, when the metal layer 300 reacts with the aqueous alkali solution, the alkali metal or the alkali earth metal is ionized. Therefore, the metal layer 300 that includes the alkali metal or the alkali earth metal may be removed. Here, the aqueous alkali solution may include one or more of sodium hydroxide (NaOH) or potassium hydroxide (KOH). Therefore, even if another metal layer is deposited on the mask 200 coated with the metal layer 300, since the deposited metal layer may be lifted off by removing the metal layer 300, the mask 200 may be cleaned easily.

Furthermore, if the mask 200 coated with the metal layer 300 that includes one or more of the alkali metal or the alkali earth metal is used in a process of depositing another metal layer of an organic electroluminescent element, contamination in the deposition process may be reduced or prevented.

More specifically, if an organic layer heterogeneous to a metal layer is coated on the mask 200 and if the mask 200 coated with the organic layer is put into a process of depositing a metal layer of an organic electroluminescent element, an organic material that forms the organic layer may be introduced onto a substrate, thereby making it difficult to deposit a metal layer of a desired purity on the substrate. Accordingly, this may lead to a reduction in the quality of the organic electroluminescent element. In addition, the organic material that forms the organic layer may be attached to wall surfaces of a metal layer deposition chamber. Therefore, contamination may continuously occur in the process of depositing the metal layer of the organic electroluminescent element.

On the other hand, if the metal layer 300 is coated on the mask 200 and if the mask 200 coated with the metal layer 300 is put into a process of depositing another metal layer of an organic electroluminescent element, even if the metal layer 300 on the mask 200 is introduced onto a substrate or attached to wall surfaces of a deposition chamber, contamination during the process may be prevented. This is because the two different metal layers existing in one deposition chamber are homogeneous layers made of metals.

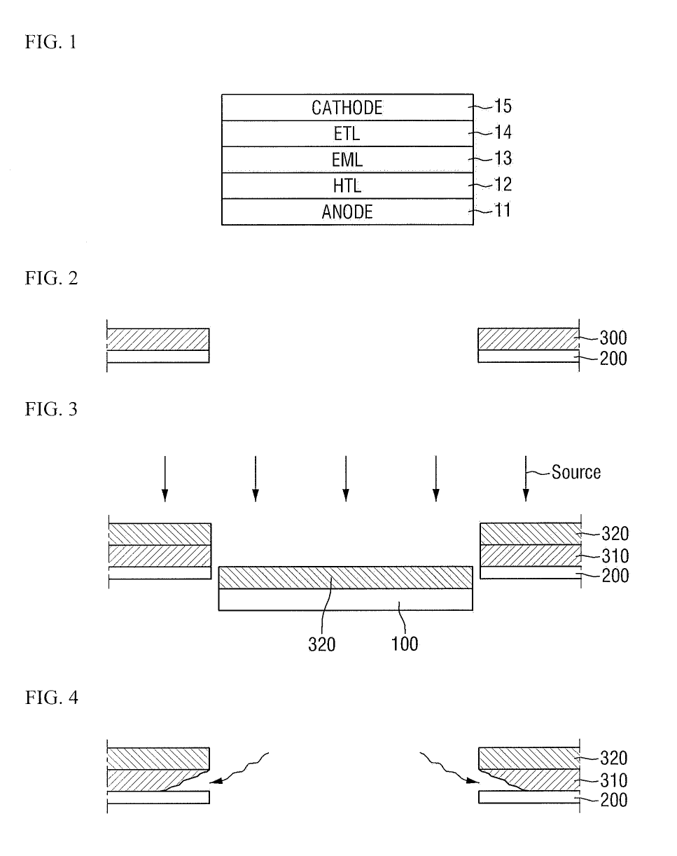

A method of cleaning a mask will now be described with reference to FIGS. 3 and 4. FIGS. 3 and 4 are cross-sectional views illustrating a method of cleaning a mask according to an embodiment. For simplicity, elements substantially identical to those of FIG. 2 are indicated by like reference numerals, and thus a repetitive description thereof will be omitted.

Referring to FIGS. 3 and 4, the method of cleaning a mask according to the present example embodiment includes preparing a mask 200 on which a first metal layer 310 and a second metal layer 320 are stacked sequentially and lifting off the second metal layer 320 by removing the first metal layer 310.

Referring to FIG. 3, the mask 200 on which the first metal layer 310 and the second metal layer 320 are stacked sequentially may be prepared using a deposition process. The mask 200 on which the first metal layer 310 and the second metal layer 320 are stacked sequentially may be obtained by using the mask 200 (which is coated with the first metal layer 310) in a process of depositing the second metal layer 320, e.g., a process used to form a feature of a display, wherein the process includes depositing the second metal layer in forming the feature of the display. The mask 200 on which the first metal layer 310 and the second metal layer 320 are stacked sequentially may also be obtained by successively performing a process of depositing the first metal layer 310 and a process of depositing the second metal layer 320 using one mask 200. In an example embodiment, these deposition processes may be a process of depositing a cathode of an organic electroluminescent element on the substrate 100.

The first metal layer 310 may be identical to the metal layer 300 described above. The second metal layer 320 may be different from the first metal layer 310 and may be more adhesive, relative to the mask 200, than the first metal layer 310. In an example embodiment, the second metal layer 320 may include an Ag-dominant Ag—Mg alloy. In addition, the second metal layer 320 may be a Yb/AgMg layer formed by alternately repeating a ytterbium (Yb) layer and an Mg—Ag alloy layer

The first metal layer 310 may be a first cathode layer which may be used as a cathode of an organic electroluminescent element. If the first cathode layer is used alone as a cathode of an organic electroluminescent element and is formed of Mg or an Mg-dominated Mg—Ag alloy, the organic electroluminescent element including the first cathode layer may have high resistance due to the Mg or Mg-dominant Mg—Ag alloy, which may affect an IR drop or a viewing angle, and/or a transmittance graph may show a downward curve toward a long wavelength. However, if the second metal layer 320 as a second cathode layer is used, e.g., if the second cathode layer is formed by alternately repeating Yb and an Ag—Mg alloy, the organic electroluminescent element including the second cathode layer may not exhibit an IR drop due to the low resistance and high electron-providing ability of Yb and Ag. It may be desirable to use the second cathode layer as a cathode of an organic electroluminescent element, instead of the first cathode layer (see FIG. 3). However, the second cathode layer may be more adhesive than the first cathode layer. Thus, if the second cathode layer is deposited directly on the mask 200, it may not be easy to clean the mask 200 by removing the second cathode layer. Hence, after the first cathode layer is deposited on the mask 200, the second cathode layer may be deposited on a surface of the mask 200 on which the first cathode layer is deposited. Then, if the first cathode layer which is relatively less adhesive is removed, the second cathode layer on the first cathode layer may be lifted off. As a result, the mask 200 may be cleaned easily.

Referring to FIG. 4, the first metal layer 310 may be removed by a wet-cleaning process. Thus, the mask 200 on which the first metal layer 310 and the second metal layer 320 are deposited sequentially may be immersed in a bath which contains an aqueous alkali solution. As a result, the first metal layer 310 may be removed. An etch rate of the first metal layer 310 for the aqueous alkali solution may be far higher than those of the second metal layer 320 and the mask 200. Therefore, the aqueous alkali solution may substantially only remove the first metal layer 310. Here, since top and bottom surfaces of the first metal layer 310 are in contact with the second metal layer 320 and the mask 200, the first metal layer 310 may be etched from its side surfaces as indicated by wavy arrows in FIG. 4. In addition, ultrasonic treatment may be performed to facilitate the removal of the first metal layer 310 in the wet-cleaning process. Ultrasonic oscillations may form gaps at an interface between the first metal layer 310 and the mask 200, and the aqueous alkali solution may enter the gaps. Accordingly, this may increase the surface area of the first metal layer 310 which contacts the aqueous alkali solution, thereby causing the first metal layer 310 to be removed more quickly.

Furthermore, at least a portion of the first metal layer 310 may be overlapped by the second metal layer 320. Thus, while the entire second metal layer 320 is on the first metal layer 310, only a portion of the first metal layer 310 may be overlapped by the second metal layer 320. In other words, the first metal layer 310 may occupy a larger area of a surface of the mask 200 than the second metal layer 320. In an example embodiment, the above configuration may be obtained by coating the first metal layer 310 all around the mask 200 and depositing the second metal layer 320 only on a surface of the mask 200. In this configuration, when the mask 200 is cleaned after a deposition process, it may be cleaned more quickly since the surface area of the first metal layer 310 which contacts the aqueous alkali solution is large.

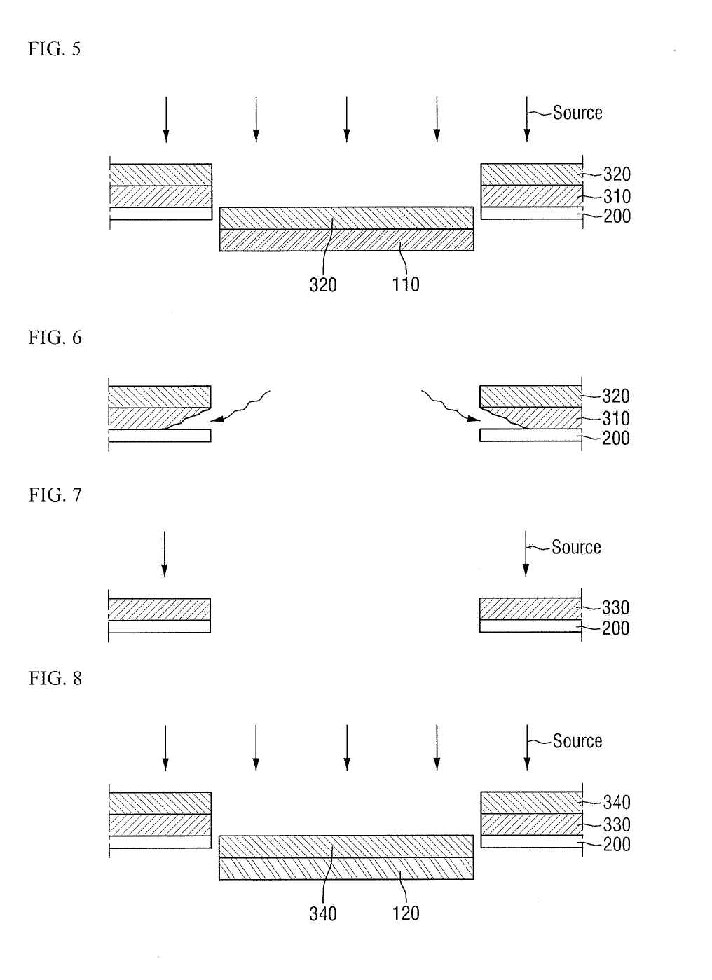

A method of manufacturing a plurality of organic electroluminescent elements according to an embodiment will now be described with reference to FIGS. 5 through 8. FIGS. 5 through 8 are cross-sectional views illustrating a method of manufacturing a plurality of organic electroluminescent elements according to an embodiment. For simplicity, elements substantially identical to those of FIGS. 1 through 4 are indicated by like reference numerals, and thus a repetitive description thereof will be omitted.

Referring to FIG. 5, the method of manufacturing a plurality of organic electroluminescent elements according to the present example embodiment includes depositing a second metal layer 320 on a mask 200 (which is coated with a first metal layer 310) and on a first substrate 110. Thus, the second metal layer 320 may be deposited on the first substrate 110 by putting the mask 200 coated with the first metal layer 310 into a deposition chamber for forming organic electroluminescent elements on the first substrate 110. In this process, the second metal layer 320 may be deposited naturally on the mask 200. In FIG. 5, the second metal layer 320 is deposited directly on the first substrate 110. However, the second metal layer 320 may also be deposited on an ETL or an EIL. The second metal layer 320 may be used as a cathode of an organic electroluminescent element.

Referring to FIG. 6, the method of manufacturing a plurality of organic electroluminescent elements according to the present example embodiment includes lifting off the second metal layer 320 by removing the first metal layer 310 from the mask 200 after the depositing of the second metal layer 320 on the mask 200 coated with the first metal layer 310 and the first substrate 110. As described above, an aqueous alkali solution may be used in this lift-off process.

Referring to FIG. 7, the method of manufacturing a plurality of organic electroluminescent elements includes coating the mask 200 with a third metal layer 330 (after the lifting off of the second metal layer 320 by removing the first metal layer 310 on the mask 200). Here, the third metal layer 330 may be made of the same material as the first metal layer 310. The coating of the mask 200 with the third metal layer 330 may be performed in another deposition chamber separate from the deposition chamber for organic electroluminescent elements. In addition, the third metal layer 330 may be coated on the mask 200 not only by deposition but also by a roller.

Referring to FIG. 8, the method of manufacturing a plurality of organic electroluminescent elements according to the present example embodiment includes depositing a fourth metal layer 340 on the mask 200 coated with the third metal layer 330 and on a second substrate 120 after the coating of the mask 200 with the third metal layer 330. Thus, the fourth metal layer 340 may be deposited on the second substrate 120 by putting the mask 200 coated with the third metal layer 330 into the deposition chamber for organic electroluminescent elements. Here, the fourth metal layer 340 may be made of the same material as the second metal layer 320. In FIG. 8, the fourth metal layer 340 is deposited directly on the second substrate 120. However, the fourth metal layer 340 may also be deposited on an ETL or an EIL. The fourth metal layer 340 may be used as a cathode layer of an organic electroluminescent element.

The organic electroluminescent elements manufactured according to the present example embodiment may include the same metal layer. However, the organic electroluminescent elements may include different metal layers, e.g., the second and fourth metal layers 320 and 340 may be different from each other. In addition, the first and third metal layers 310 and 330 may be different from each other. Here, the first and third metal layers 310 and 330 may be less adhesive, relative to the mask 200, than the second and fourth metal layers 320 and 340.

As described above, a plurality of organic electroluminescent elements may be manufactured sequentially using the method of manufacturing a plurality of organic electroluminescent elements according to the present example embodiment. In addition, the precision and uniformity of a deposition pattern may be ensured by adding a simple and easy process of cleaning the mask 200 between each process of manufacturing an organic electroluminescent process.

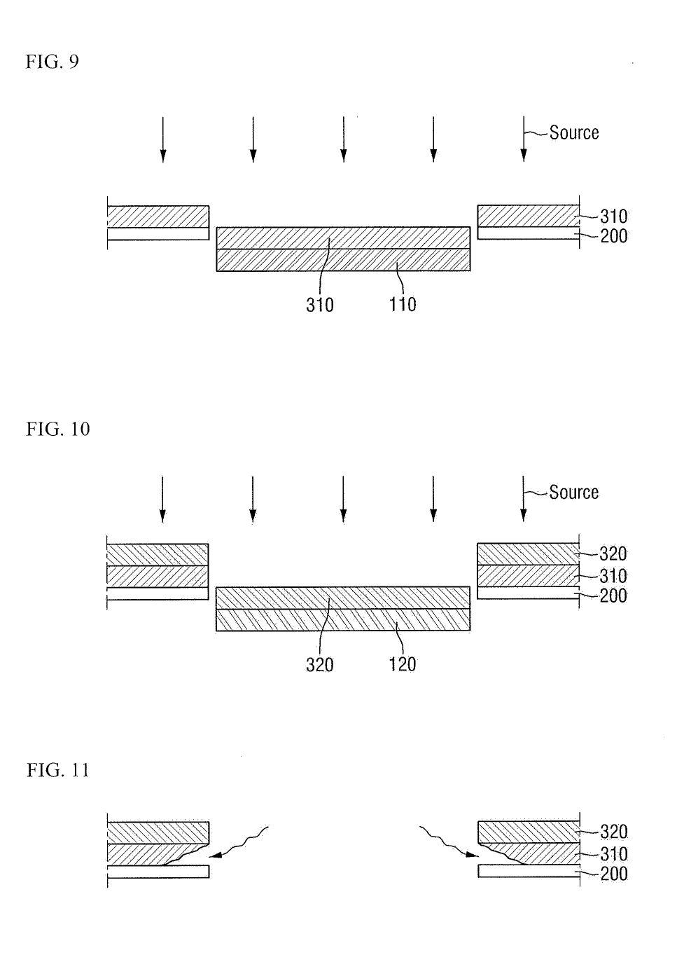

FIGS. 9 through 11 are cross-sectional views illustrating a method of manufacturing a plurality of organic electroluminescent elements according to another embodiment. For simplicity, elements substantially identical to those of FIGS. 5 through 8 are indicated by like reference numerals, and thus a repetitive description thereof will be omitted.

Referring to FIG. 9, the method of manufacturing a plurality of organic electroluminescent elements according to the present example embodiment includes depositing a first metal layer 310 on a mask 200 and on a first substrate 110. Unlike in the manufacturing method according to the previous embodiment, in the manufacturing according to the present example embodiment, the first metal layer 310 is deposited on the first substrate 110. Thus, a process of depositing the first metal layer 310 only on the mask 200 is omitted. Instead, a process of depositing the first metal layer 310 on the mask 200 is included in a deposition process for manufacturing an organic electroluminescent element, in which the first metal layer 310 is deposited on the first substrate 110. This may promote process efficiency. In FIG. 9, the first metal layer 310 is deposited directly on the first substrate 110. However, the first metal layer 310 may also be deposited on an ETL or an EIL. The first metal layer 310 may be used as a cathode of an organic electroluminescent element.

Referring to FIG. 10, the method of manufacturing a plurality of organic electroluminescent elements according to the present example embodiment includes depositing a second metal layer 320 on the mask 200 having the first metal layer 310 deposited thereon and on a second substrate 120, after the depositing of the first metal layer 310 on the mask 200 and the first substrate 110. The current process may be substantially identical to the process of FIG. 5.

Referring to FIG. 11, the method of manufacturing a plurality of organic electroluminescent elements includes lifting off of the second metal layer 320 by removing the first metal layer 310 on the mask 200 after the depositing of the second metal layer 320 on the mask 200 having the first metal layer 310 deposited thereon and the second substrate 120. The current process may be substantially identical to the process of FIG. 6.

As described above, two different types of organic electroluminescent elements may be manufacturing using the method of manufacturing a plurality of organic electroluminescent elements according to the present example embodiment. Thus, an organic electroluminescent element may be manufactured, the electroluminescent element including the first metal layer 310 and another organic electroluminescent element including the second metal layer 320 which is more adhesive, relative to the mask 200, than the first metal layer 310. Therefore, product diversity may be ensured by building a plurality of optimized manufacturing lines for organic electroluminescent elements in an organic electroluminescent element manufacturing factory.

By way of summation and review, a stacked structure of an organic electroluminescent element may be formed by a deposition method using a mask. Fine patterns of organic layers including an emission layer and intermediate layers may be formed by a deposition method using a fine metal mask (FMM). However, since there is no need to form fine patterns in metal layers such as the anode and the cathode, the metal layers may be formed by a deposition method using an open mask.

Such a stacked structure of an organic electroluminescent element may require high precision. Therefore, it may be important to prevent contamination in a deposition process. In particular, since a mask may serve as a medium for introducing contaminants to a deposition process, it may be essential to clean the mask before and after the mask is put into the deposition process.

In addition, since organic electroluminescent elements having the same stacked structure are mass-produced on a line, a mask used to form the stacked structure may be used repeatedly. However, once a mask is put into a deposition process, a deposition material is deposited on the mask. If the mask having the deposition mask deposited thereon is immediately input into a next deposition process, the deposition material may cause contamination during the deposition process or non-uniformity of a deposition pattern. Therefore, it may be required to clean the mask between deposition processes.

In a stacked structure of an organic electroluminescent element, a metal layer may be more adhesive than an organic layer. Therefore, it may be difficult to completely clean a mask after the metal layer is deposited using the mask. In addition, a more adhesive metal layer may be more difficult to clean from the mask.

As described above, embodiments may provide a method of cleaning a mask used to deposit a metal layer of an organic electroluminescent element. Embodiments may also provide a method of manufacturing a plurality of organic electroluminescent elements using a mask which is used to deposit a metal layer of an organic electroluminescent element and which may be cleaned easily. According to embodiments, a mask used to deposit a metal layer of an organic electroluminescent element may be cleaned easily. According to embodiments, a plurality of high-quality organic electroluminescent elements may be manufactured sequentially by a precise deposition process.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of cleaning a mask, the method comprising:
preparing a mask on which a first metal layer and a second metal layer are stacked sequentially; and
lifting off the second metal layer by removing the first metal layer.

2. The method as claimed in claim 1, wherein the first metal layer includes one or more of an alkali metal or an alkali earth metal.

3. The method as claimed in claim 2, wherein the first metal layer includes the alkali earth metal, the alkali earth metal being magnesium.

4. The method as claimed in claim 3, wherein the first metal layer further includes silver, wherein a ratio of the number of magnesium atoms to the number of silver atoms is from 1:1 to about 10:1.

5. The method as claimed in claim 1, wherein the second metal layer is more adhesive, relative to the mask, than the first metal layer.

6. The method as claimed in claim 5, wherein the second metal layer includes ytterbium and an alloy, the alloy being an alloy of silver and magnesium in which silver is dominant, the second metal layer being formed in connection with forming a cathode layer.

7. The method as claimed in claim 6, wherein the second metal layer is formed by alternately depositing the ytterbium and the alloy.

8. The method as claimed in claim 1, wherein at least a portion of the first metal layer is overlapped by the second metal layer.

9. The method as claimed in claim 1, wherein the lifting off of the second metal layer by removing the first metal layer includes removing the first metal layer using an aqueous alkali solution.

10. The method as claimed in claim 9, wherein the aqueous alkali solution includes one or more of sodium hydroxide or potassium hydroxide.

11. A method of manufacturing a plurality of organic electroluminescent elements, the method comprising:
depositing a second metal layer, the second metal layer being deposited on a first substrate and on a mask coated with a first metal layer;
lifting off the second metal layer by removing the first metal layer from the mask;
coating the mask with a third metal layer; and
depositing a fourth metal layer on a second substrate and on the mask coated with the third metal layer.

12. The method as claimed in claim 11, wherein the first metal layer includes one or more of an alkali metal or an alkali earth metal.

13. The method as claimed in claim 12, wherein the first metal layer and the third metal layer are made of a same material.

14. The method as claimed in claim 11, wherein the second metal layer is more adhesive, relative to the mask, than the first metal layer.

15. The method as claimed in claim 14, wherein the second metal layer and the fourth metal layer are made of a same material.

16. The method as claimed in claim 11, wherein the lifting off of the second metal layer by removing the first metal layer includes removing the first metal layer using an aqueous alkali solution.

17. A method of manufacturing a plurality of organic electroluminescent elements, the method comprising:
depositing a first metal layer on a first substrate and on a mask;
depositing a second metal layer on a second substrate and on the mask having the first metal layer deposited thereon; and
lifting off the second metal layer by removing the first metal layer from the mask.

18. The method as claimed in claim 17, wherein the first metal layer includes one or more of an alkali metal or an alkali earth metal.

19. The method as claimed in claim 17, wherein the second metal layer is more adhesive, relative to the mask, than the first metal layer.

20. The method as claimed in claim 17, wherein the lifting off of the second metal layer by removing the first metal layer includes removing the first metal layer using an aqueous alkali solution.

21. A mask coated with a metal layer, the metal layer including one or more of an alkali metal or an alkali earth metal.

22. The mask as claimed in claim 21, wherein the metal layer includes the alkali earth metal, the alkali earth metal being magnesium.

23. The mask as claimed in claim 22, wherein the metal layer further includes silver, and a ratio of the number of magnesium atoms to the number of silver atoms is from 1:1 to about 10:1.
